(19) United States
(12) Patent Application Publication
(10) Pub. No.: US 2003/0111337 A1
(43) Pub. Date: Jun. 19, 2003

(54) Method and apparatus for monitoring sputter etch process

(76) Inventors: Chien-Chia Lin, Hsinchu (TW); Shih-Liang Chou, Hsinchu (TW); Kuo-Wei Shyu, Hsinchu (TW)

Correspondence Address: J.C. Patents, Inc., Suite 250, 4 Venture, Irvine, CA, 92618, US

(21) Appl. No.: 10/115,755

(22) Filed: Apr. 3, 2002

(30) Foreign Application Priority Data
Dec. 18, 2001 (TW) 90131287

(51) Int. Cl. C23C 14/32

(52) U.S. Cl. 204/192.33; 204/298.31; 204/298.32; 204/192.32

(57) ABSTRACT

An apparatus and a method for monitoring the ion concentration in an etching chamber of a sputter etch process are described, wherein the DC bias of a pre-clean process for a sputter etch process is acquired. The parameters of the pre-clean process for the sputter etch process are then adjusted according to the value of the monitored DC bias. The DC bias thus varies within a certain range to provide a steady control of the ion concentration and to reduce the defects formed in the wafer.

### CROSS-REFERENCE TO RELATED APPLICATION

This application claims the priority benefit of Taiwan application serial no. 90131287, filed on Dec. 18, 2001.

### BACKGROUNDING OF THE INVENTION

1. Field of Invention

The present invention relates to a sputter etch process. More particularly, the present invention relates to a method and an apparatus that monitors the ion concentration in an etching chamber during a sputter etch process.

2. Description of Related Art

During the manufacturing of a wafer, the native oxide layer generated on a wafer surface has to be removed by a sputter etch process in order to lower and to stabilize the resistance at the connecting points of the conductive lines. To remove the native oxide layer on a wafer surface, a low radio frequency plasma (400 KHZ) is employed. Moreover, a DC bias is also used to balance an electric current and an ionic current in order to accelerate the ions to the wafer surface to provide the sputter etch effect. The DC bias is a negative voltage established in a reaction chamber, and parameters that affect the DC bias mainly include the power and the pressure of the high radio frequency (13.56 MHz). The hardware of the system also affects the performance of the DC bias. The industry, conventionally, does not monitor or control the DC bias of a sputter etch process. The yield of wafer is thus adversely affected when drastic changes occur in DC bias.

### SUMMARY OF THE INVENTION

Accordingly, the present invention provides a method and an apparatus for monitoring the ion concentration in an etching chamber during a sputter etch process, wherein defects formed in the wafer due to drastic changes in the DC bias are prevented.

The present invention provides a method and an apparatus for monitoring the ion concentration in an etching chamber during a sputter etch process by monitoring the DC bias generated in the etching chamber. The apparatus of the present invention comprises at least a waveform acquisition device and an evaluation device. The waveform acquisition device is coupled to the etching chamber. The waveform acquisition device detects the amplitude of the DC bias and outputs a signal representing the amplitude of the DC bias in the etching chamber. The evaluation device is coupled to the waveform acquisition device to receive the output from the waveform acquisition device, compares the output from the waveform acquisition device with a predetermined range of DC bias. The evaluation device also determines whether the amplitude of the DC bias in the etching chamber exceeds the predetermine range of DC bias and a signal for notifying a next treatment step is then issued accordingly.

According to a preferred embodiment of the present invention, the apparatus that monitors the ion concentration in the etching chamber during a sputter etch process further comprises a DC bias monitoring range setting circuit and an alarming system. The DC bias monitoring range setting circuit is used to predetermine a range of the DC bias. The alarming system is used to receive the signal output from the evaluation device and issue an alarm signal accordingly. The apparatus that monitors the ion concentration in an etching chamber during a sputter etch process of the present invention applies a predetermine range of DC bias to control the DC bias to vary within the predetermine range of DC bias in the etching chamber. The ion concentration in the etching chamber is thus steadily controlled to improve the yield of the wafer.

The present invention provides a method for monitoring the ion concentration in an etching chamber during a sputter etch process, wherein the DC bias generated in the etching chamber is monitored. According to the method of the present invention, the value of the DC bias is acquired in real time, output and compared with a predetermine range of DC bias to determine whether the DC bias falls within the predetermine range. A signal for notifying a next treatment step is further output if the DC bias exceeds the predetermine range.

According to a preferred embodiment of the present invention, the method for monitoring the ion concentration in the etching chamber during a sputter etch process further comprises a step of inputting the aforementioned predetermine range.

Since, during the sputter etch process, the DC bias of the pre-clean process alters drastically, adversely affecting the yield of the wafer. The industry, however, does not conventionally monitor the DC bias of the process. Poor yield of the wafer is thereby resulted due to the drastic alterations of the DC bias. The present invention thereby provides an apparatus and a method for monitoring the ion concentration in the etching chamber during a sputter etch process by acquiring the DC bias generated in the pre-clean process for the sputter etch process and adjusting the parameters of the pre-clean process for the sputter etch process according to the monitored value of the DC bias. The DC bias is adjusted to vary within a certain range to steadily control the ion concentration in the etching chamber. The defects in the wafer are thus reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is diagram illustrating the apparatus and the method for monitoring the ion concentration in the etching chamber during a sputter etch process according to a preferred embodiment of the present invention;

FIG. 2 is a block diagram illustrating the apparatus for monitoring the ion concentration in the etching chamber during a sputter etch process according to the preferred embodiment of a present invention;

FIG. 3 is a flow diagram illustrating the method for monitoring the ion concentration in the etching chamber during a sputter etch process according to the preferred embodiment of the present invention; and

FIG. 4 is a flow diagram illustrating the method for monitoring the ion concentration in the etching chamber during a sputter etch process according to another preferred embodiment of the present invention.

### DESCRIPTION OF THE PREFERRED EMBODIMENTS

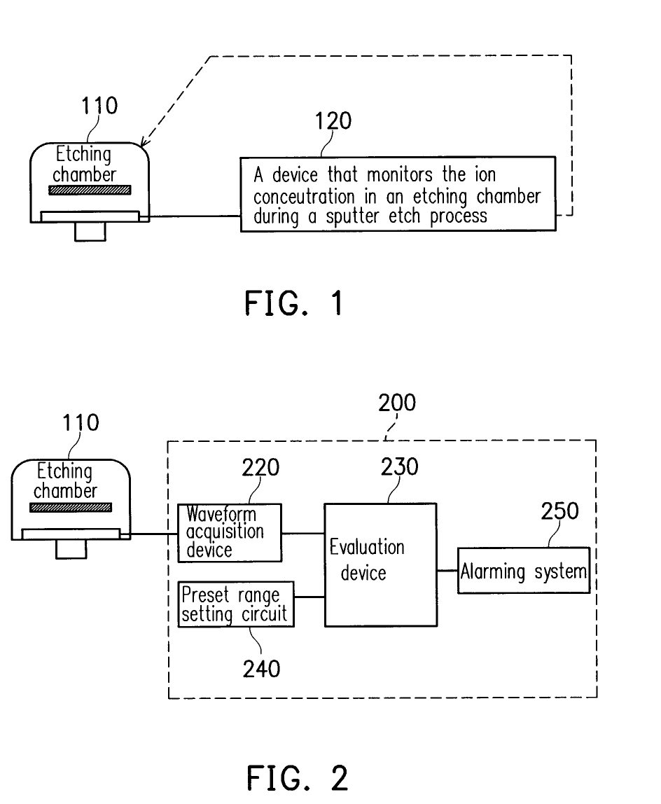

FIG. 1 is diagram illustrating the apparatus and the method for monitoring the ion concentration in the etching chamber during a sputter etch process according to a preferred embodiment of the present invention. As shown in FIG. 1, the apparatus 120 that monitors the ion concentration in the etching chamber during a sputter etch process acquires in real time the DC bias generated in the etching chamber 10. A signal represent the DC bias acquired by the apparatus 120 is output, compared with a predetermine range of DC bias and determined whether the DC bias generated in the etching chamber 110 exceeds a predetermine range of DC bias. A signal is further output by the apparatus if the DC bias exceeds the predetermine range. By referencing to the signal that is output by the apparatus when the DC bias exceeds the predetermine range, the parameters of the pre-clean process for the sputter etch process can be adjusted accordingly to steadily control the ion concentration in the etching chamber. The ion concentration thus varies only within a certain range to reduce defects being formed in the wafer.

FIG. 2 is a block diagram illustrating the DC bias monitoring apparatus for a sputter etch process according to a preferred embodiment of the present invention. As shown in FIG. 2, the apparatus 200 that monitors the ion concentration in the etching chamber during a sputter etch process includes a waveform acquisition device 220, an evaluation device 230, a DC monitoring range setting circuit 240 and an alarming system 250.

Theoretically, the DC bias of the pre-clean process for the sputter etch process is used to balance the electric current and the ionic current in the etching chamber. The sputter effect is achieved by successfully accelerating the ions to the wafer surface by the DC bias. The waveform acquisition device 220 of the apparatus 200 of the present invention is coupled to the etching chamber 210 to acquire in real time the DC bias and to output the DC bias. The waveform acquisition device 220 includes a waveform recorder or an oscilloscope that can receive a DC voltage. The evaluation device 230 of the present invention is coupled to the waveform acquisition device 220. The evaluation device compares the DC bias detected by the waveform acquisition device 220 with the predetermine range of DC bias set by the DC bias monitoring range setting circuit 240. The evaluation device 230 also determines whether the DC bias falls within the predetermine range of DC bias and then outputs a signal when the DC bias exceeds the predetermine range.

The predetermine range of DC bias is determined by the DC bias monitoring range setting circuit 240. The predetermine range of DC bias is input to the evaluation device 230, where the predetermine value is compared with the DC bias that is output from the waveform acquisition device 220. If the DC bias output from the waveform acquisition device 220 exceeds the predetermine range of DC bias, a signal is output and an alarm signal is issued from an alarming system 250.

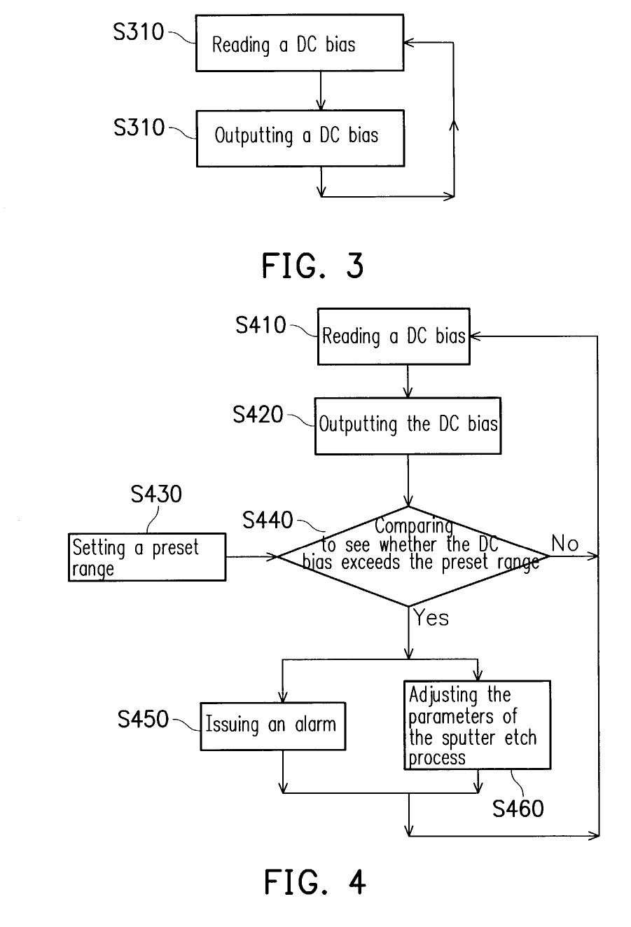

In the method for monitoring the DC bias of a sputter etch process in accordance to the preferred embodiment of the present invention, the ion concentration in the etching chamber is monitored during a sputter etch process, wherein the DC bias generated in the etching chamber is monitored. Referring to FIG. 3, the method of the present invention comprises acquiring the DC bias in real time (S310), followed by outputting the DC bias (S320).

Another preferred embodiment of the present invention provides a method to further achieve the monitoring effect. Referring to FIG. 4, a DC bias (S410) is acquired in real time and the DC bias is output (S420). A predetermine range of DC bias is also input (S430) and compared with the DC bias to determine whether the DC bias exceeds the predetermine range of DC bias (S440). If the compared result indicates that the DC bias exceeds the predetermine range of DC bias, a signal is issued to trigger an alarm (S450) according to the signal. According to the present invention, based on the compared result, the parameters for the sputter etch process can be further adjusted (S460) to control the DC bias to vary within the predetermine range of DC bias in order to obtain an optimal ion concentration for the process.

As well known to those skilled in the art, the present invention is not limited to using the DC bias monitoring range setting circuit 240. The predetermine range of DC bias can be set within the DC bias monitoring device 200 or set by other type of monitoring system. Moreover, the alarm signal is not necessary issued from an alarming system 250. An operator can be notified about the compared result through other type of display or the compared result is input to other control device to further control the sputter etch process, like stopping the operation of the etching machine.

Table 1 summarizes the sputter etch results before and after the application of the apparatus and the method for monitoring the ion concentration in the etching chamber of a sputter etch process according to the present invention. The first row in Table 1 is the machine number. Machine 6 to Machine 10 employs the monitoring apparatus and the method for monitoring the ion concentration in the etching chamber of a sputter etch process of the present invention. Machine 1 to Machine 5 perform the sputter etch process without the application of the apparatus or method of the present invention. Row 2 in Table 1 is the total count of the defective particles in the wafer, wherein Row 3 in Table 2 is the area count of the slightly larger defective particles in the wafer. Based on Table 1, the application of the monitoring apparatus and method of the present invention for monitoring the ion concentration in the etching chamber in a sputter etch process provides an improvement both in terms of the total count and the area count of the defective particles.

TABLE 1

| | Machine Number | | | | | | | | | |
|---|---|---|---|---|---|---|---|---|---|---|
| | 1 | 2 | 3 | 4 | 5 | 6 | 7 | 8 | 9 | 10 |
| Total Count | 56 | 60 | 53 | 110 | 75 | 24 | 30 | 22 | 21 | 11 |
| Area Count | 13 | 23 | 11 | 29 | 33 | 10 | 9 | 10 | 10 | 5 |

Accordingly, the method for monitoring the ion concentration in an etching chamber during a sputter etch process of the present invention reads a DC bias of a pre-clean process for the sputter etch process. By comparing the DC bias of the pre-clean process, the parameters of the pre-clean process is adjusted accordingly to vary within a predetermine range such that the ion concentration in the etching chamber is steadily controlled. Having the ion concentration to vary within a predetermine range, the defects in the wafer are thereby reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for monitoring an ion concentration in an etching chamber during a sputter etch process, the process using a plasma and a DC bias to bombard a surface to be treated with ions, the method comprising:
a step of sensing an amplitude of the DC bias during the sputter etch process and outputting a first signal indicating an amplitude of the DC bias.

2. The method of claim 1, wherein when the amplitude of the DC bias exceeds a specific range, a second signal is issued for notifying a next treatment step.

3. The method of claim 2, further comprises terminating an operation of a sputter etch machine according to the second signal.

4. The method of claim 1, further comprises a step of adjusting other parameters according to the amplitude of the DC bias to stabilize the DC bias within a certain range.

5. The method of claim 1, wherein the first signal indicating the amplitude of the DC bias is output and displaced by an oscilloscope.

6. The method of claim 1, wherein the first signal indicating the amplitude of the DC bias is output and displaced by a waveform recorder.

7. The method of claim 2 further comprising a step of setting a range of the amplitude of the DC bias before the step of sensing the DC amplitude.

8. An apparatus of sputter etch, which uses a plasma and a DC bias to bombard a surface to be treated in an etching chamber with ions, being characterized by:
a DC bias monitoring device for sensing an amplitude of the DC bias and outputting a first signal indicating the amplitude during the process.

9. The apparatus of claim 8, wherein the DC bias monitoring device further comprises:
a waveform acquisition device coupled to the etching chamber to sense the DC bias in a real time and to output the first signal representing the amplitude of the DC bias.

10. The apparatus of claim 9, wherein the DC monitoring device further comprises:
an evaluation device to receive and compare the DC bias amplitude that is sensed by the DC bias monitoring device with a predetermined range of DC bias and to issue a signal when the DC bias amplitude exceeds the predetermine range of DC bias.

11. The apparatus of claim 10, wherein the DC monitoring device further comprises:
a DC monitoring range setting circuit to set the predetermined range of DC bias.

12. The apparatus of claim 10, wherein the DC monitoring device further comprises:
an alarming system to issue an alarm signal according to the second signal.

13. The apparatus of claim 9, wherein the waveform acquisition device is an oscilloscope.

14. The apparatus of claim 9, wherein the waveform acquisition device is a waveform recorder.
